(19) United States
(12) Patent Application Publication
(10) Pub. No.: US 2026/0082527 A1
(43) Pub. Date: Mar. 19, 2026

(54) ELECTRONIC DEVICE, DISPLAY DEVICE, AND METHOD OF MANUFACTURING DISPLAY DEVICE

(71) Applicant: Samsung Display Co., Ltd., Yongin-si (KR)

(72) Inventors: HIDEKAZU HAYASHI, Yongin-si (KR); JAHUN KOO, Yongin-si (KR); KYU-TAE PARK, Yongin-si (KR); BYUNG JIN PARK, Yongin-si (KR); TAEK-SUN SHIN, Yongin-si (KR); Jangun CHOI, Yongin-si (KR)

(21) Appl. No.: 19/265,288

(22) Filed: Jul. 10, 2025

(30) Foreign Application Priority Data
Sep. 19, 2024 (KR) 10-2024-0126748

(51) Int. Cl. H05K 7/20

(52) U.S. Cl. CPC H05K 7/20963

(57) ABSTRACT

A display device, a method of manufacturing the display device, and an electronic device including the display device are disclosed. The display device may include a display panel, a vapor chamber spaced and/or apart from a rear surface of the display panel, and an adhesive assembly that is between the display panel and the vapor chamber and attaches the vapor chamber to the rear surface of the display panel, wherein the adhesive assembly includes an adhesive layer applied to the rear surface of the display panel, a first adhesive at a central portion of a rear surface of the adhesive layer, a second adhesive applied onto the rear surface of the adhesive layer and around the first adhesive, a third adhesive applied onto the rear surface of the adhesive layer and around the second adhesive, and a fourth adhesive on rear surfaces of the second adhesive and the third adhesive.

### CROSS-REFERENCE TO RELATED APPLICATION

The present application claims priority to and the benefit of Korean Patent Application No. 10-2024-0126748, filed on Sep. 19, 2024, in the Korean Intellectual Property Office, the entire disclosure of which is incorporated herein by reference.

### BACKGROUND

### 1. Field

One or more embodiments of the present disclosure relate to a display device, a method of manufacturing the display device, and an electronic device including the display device.

### 2. Description of the Related Art

Electronic devices, such as smartphones, digital cameras, laptop computers, navigation systems, and/or smart televisions, that provide images to a user include display devices for displaying the images. The display devices generate an image and provide the generated image to a user through a display screen.

The display devices may include a heat dissipating member to efficiently dissipate heat generated if (e.g., when) a display panel emits a light. The display devices may also include, along with the heat dissipating member, a vapor chamber including a refrigerant, such as a phase change material. The display panel and the vapor chamber may be attached to each other by a pressure-sensitive adhesive applied in one or more layers.

### SUMMARY

One or more aspects of embodiments of the present disclosure are directed toward a display device capable of reducing a void and a temperature difference in the display device, a method of manufacturing the display device, and an electronic device including the display device.

Additional aspects of embodiments will be set forth in part in the description which follows and, in part, will be apparent from the description or may be learned by practice of the presented embodiments of the disclosure.

According to one or more embodiments, a display device includes a display panel, a vapor chamber arranged to be spaced and/or apart (e.g., spaced apart or separated) from a rear surface of the display panel, and an adhesive assembly that is between the display panel and the vapor chamber and attaches the vapor chamber to the rear surface of the display panel, wherein the adhesive assembly includes an adhesive layer applied to (or on) the rear surface of the display panel, a first adhesive applied to (or on) a central portion of a rear surface of the adhesive layer, a second adhesive applied to (or on) the rear surface of the adhesive layer and around (e.g., surrounding) the first adhesive, a third adhesive applied to (or on) the rear surface of the adhesive layer and around (e.g., surrounding) the second adhesive, and a fourth adhesive applied to (or on) rear surfaces of the second adhesive and the third adhesive, and the second adhesive and the third adhesive include a thermally expandable microcapsule.

According to one or more embodiments, a method of manufacturing a display device includes applying an adhesive layer to one surface of a display panel, applying a first adhesive to a central portion of a rear surface of the adhesive layer, applying a second adhesive and a third adhesive to an edge of the rear surface of the adhesive layer, applying a fourth adhesive to rear surfaces of the second adhesive and the third adhesive, laminating a vapor chamber on the fourth adhesive, and thermally expanding the second adhesive and the third adhesive through heating in a state in which the vapor chamber is laminated on the fourth adhesive, wherein the applying of the second adhesive and the third adhesive to the edge of the rear surface of the adhesive layer includes applying a pressure sensitive adhesive (PSA) containing a thermally expandable microcapsule.

According to one or more embodiments, an electrode device may include a display panel, a vapor chamber arranged to be spaced and/or apart (e.g., spaced apart or separated) from a rear surface of the display panel, and an adhesive assembly between the rear surface of the display panel and the vapor chamber and arranged to attach the vapor chamber to the rear surface of the display panel, wherein the adhesive assembly includes an adhesive layer arranged on the rear surface of the display panel, a first adhesive arranged at a central portion of a rear surface of the adhesive layer, a second adhesive around (e.g., surrounding) the first adhesive on the rear surface of the adhesive layer, a third adhesive around (e.g., surrounding) the second adhesive on the rear surface of the adhesive layer, and a fourth adhesive arranged on rear surfaces of the second adhesive and the third adhesive, and wherein the second adhesive and the third adhesive include a thermally expandable microcapsule.

### BRIEF DESCRIPTION OF THE DRAWINGS

The above and other aspects and features of certain embodiments of the present disclosure will become more apparent by describing in more detail one or more embodiments thereof with reference to the accompanying drawings.

FIG. 1 is a cross-sectional view illustrating a display device according to one or more embodiments of the present disclosure.

FIG. 2 is a plan view illustrating a portion of the display device according to one or more embodiments of the present disclosure.

FIG. 3 is a flowchart illustrating a method of manufacturing a display device according to one or more embodiments of the present disclosure.

FIGS. 4-9 are views sequentially illustrating the method of manufacturing a display device according to the flowchart of FIG. 3.

FIG. 10 is a cross-sectional view illustrating a display device according to one or more embodiments of the present disclosure.

FIG. 11 is a plan view illustrating a portion of the display device according to one or more embodiments of the present disclosure.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

In the specification, the expression that a first component (or an area, a layer, a part, a portion, and/or the like) is “arranged on”, “connected with”, or “coupled to” a second component refers to that the first component is directly arranged on/connected with/coupled to the second component or refers to that a third component is interposed therebetween. In contrast, if (e.g., when) a first component is referred to as being “directly on”, “directly connected with”, or “directly coupled to” another component, there may be no intervening components present therebetween.

The same reference numerals refer to substantially the same components. Further, in the drawings, the thickness, the ratio, and the dimension of components may be exaggerated to effectively or suitably illustrate the technical contents of the present disclosure.

The expression “and/or” includes one or more combinations which associated components are capable of defining.

Although the terms “first”, “second”, and/or the like may be used to describe one or more suitable components, the components should not be limited by the terms. The terms are only used to distinguish one component from another component. For example, without departing from the spirit and scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, and/or the like are used to describe the correlation of components illustrated in the accompanying drawings. The terms that are relative in concept are described based on a direction illustrated in drawings.

It will be understood that the terms “include”, “have”, “including”, “having”, and/or the like specify the presence of features, numbers, steps, operations, elements, or components, described in the specification, and/or a (e.g., any suitable) combination thereof, and do not exclude in advance the presence or additional possibility of one or more other features, numbers, steps, operations, elements, or components and/or a (e.g., any suitable) combination thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The utilization of “may,” if (e.g., when) describing embodiments of the present disclosure, refers to “one or more embodiments of the present disclosure.”

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein, is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

In the context of the present disclosure and unless otherwise defined, the terms “use,” “using,” and “used” may be considered synonymous with the terms “utilize,”“utilizing,”and “utilized,”respectively.

Unless otherwise defined, all terms (including technical terms and scientific terms) used in the specification have substantially the same meaning as commonly understood by those skilled in the art to which the present disclosure belongs. Furthermore, terms, such as terms defined in the dictionaries that are generally used, should be interpreted as having a meaning consistent with the meaning in the context of the related technology and should not be interpreted in overly ideal or overly formal meanings unless explicitly defined herein.

Hereinafter, one or more embodiments of the present disclosure will be described in more detail with reference to the accompanying drawings.

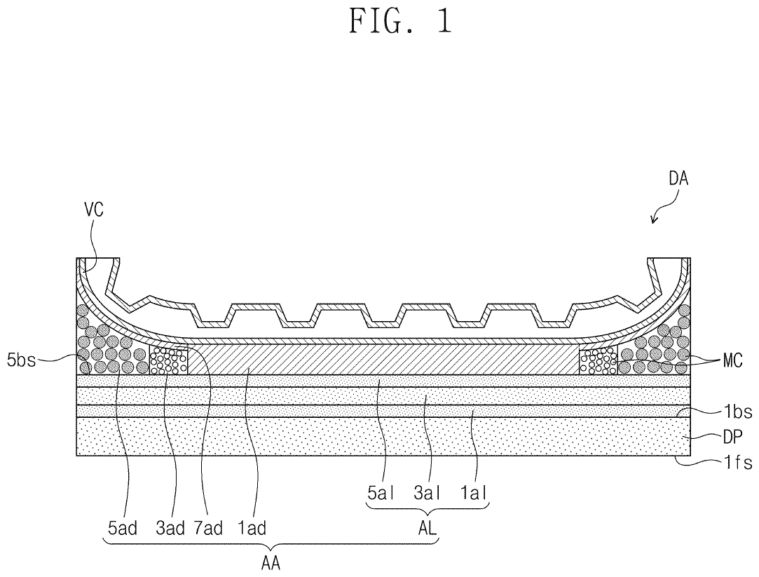

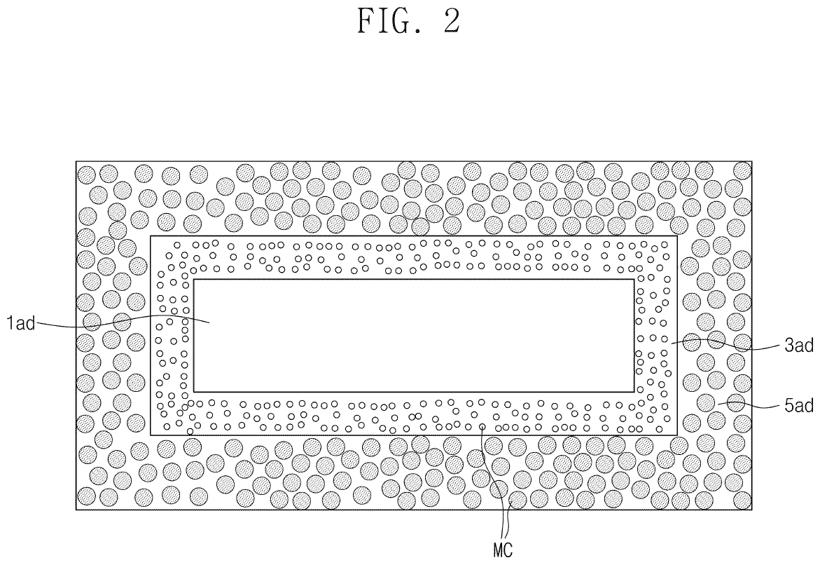

FIG. 1 is a cross-sectional view illustrating a display device according to one or more embodiments of the present disclosure, and FIG. 2 is a plan view illustrating a portion of the display device according to one or more embodiments of the present disclosure.

Referring to FIGS. 1 and 2, a display device DA may include a display panel DP, a vapor chamber VC, and an adhesive assembly AA. The display panel DP may be a flexible display panel DP. The display panel DP may be to display an image on a front surface 1fs. The display panel DP according to one or more embodiments of the present disclosure may be a light emitting display panel DP, but embodiments of the present disclosure are not limited thereto. For example, the display panel DP may be an organic light emitting display panel DP or an inorganic light emitting display panel DP. A light emitting layer of the organic light emitting display panel DP may include an organic light emitting material. A light emitting layer of the inorganic light emitting display panel DP may include a quantum dot, a quantum rod, and/or the like. Hereinafter, the display panel DP may be described as an organic light emitting display panel.

The vapor chamber VC may be arranged to be spaced and/or apart (e.g., spaced apart or separated) from a rear surface 1bs of the display panel DP. The vapor chamber VC may include a first plate UP and a second plate LP. The first plate UP may be coupled to the adhesive assembly AA. The second plate LP may be coupled to the first plate UP and may have a bent shape. However, embodiments of the present disclosure are not limited thereto. The second plate LP may have a plurality of embossed structures arranged at regular intervals. Distal ends of the first plate UP and the second plate LP may be sealed. The vapor chamber VC may be to discharge heat generated from the display panel DP to another inner space of the display device DA or the outside. For example, the vapor chamber VC may seal a phase change material (PCM) between the first plate UP and the second plate LP of which the distal ends are sealed and thus discharge the heat generated from the display panel DP to the outside.

The adhesive assembly AA may attach the display panel DP and the vapor chamber VC to each other. The adhesive assembly AA may include an adhesive layer AL, a first adhesive 1ad, a second adhesive 3ad, a third adhesive 5ad, and a fourth adhesive 7ad. Each of the adhesive layer AL, the first adhesive 1ad, the second adhesive 3ad, the third adhesive 5ad, and the fourth adhesive 7ad may include (e.g., be) a pressure sensitive adhesive (PSA).

The adhesive layer AL may be applied to (or on) the rear surface 1bs of the display panel DP. The adhesive layer AL may be arranged to provide a flat surface (e.g., a substantially flat surface). The adhesive layer AL may include a first adhesive layer 1al, a second adhesive layer 3al, and a third adhesive layer 5al.

The first adhesive layer 1al may be directly applied to (or on) the rear surface 1bs of the display panel DP. The second adhesive layer 3al may be applied to (or on) the first adhesive layer 1al. The second adhesive layer 3al may be made of a material different from that of the first adhesive layer 1al. In more detail, the second adhesive layer 3al may include polyethylene terephthalate (PET).

The third adhesive layer 5al may be applied to (or on) the second adhesive layer 3al. The third adhesive layer 5al and the first adhesive layer 1al may include substantially the same material. For example, the third adhesive layer 5al and the first adhesive layer 1al may include the PSA.

The first adhesive 1ad may be applied to (or on) a rear surface 5bs of the adhesive layer AL. In more detail, the first adhesive 1ad may be applied to (or on) a central portion (or a central area) of the rear surface 5bs of the adhesive layer AL.

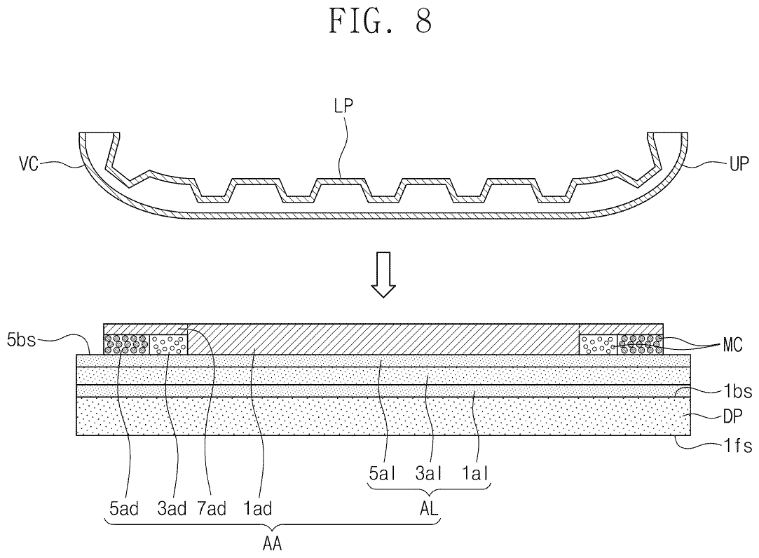

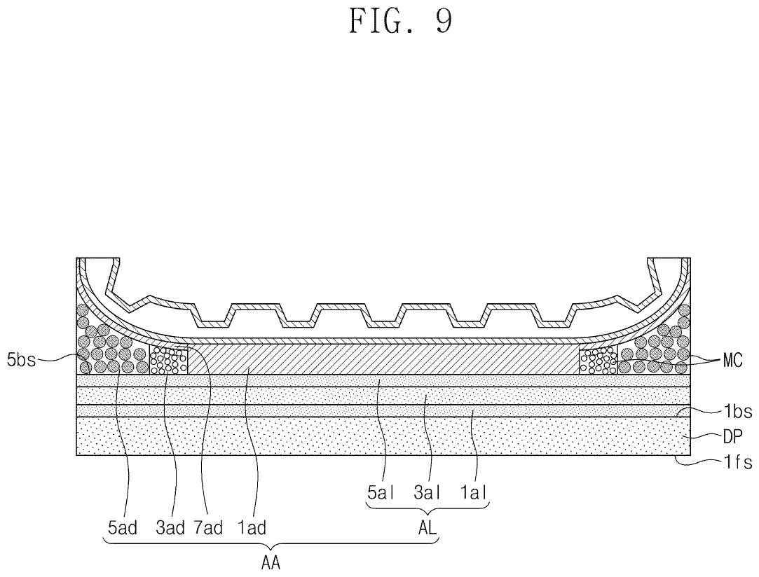

The second adhesive 3ad may be applied to (or on) the rear surface 5bs of the adhesive layer AL. In more detail, the second adhesive 3ad may be around (e.g., surround) the first adhesive 1ad on the rear surface 5bs of the adhesive layer AL as illustrated in FIG. 2. A thickness of the second adhesive 3ad may be in a range of about 20 μm to about 30 μm, but embodiments of the present disclosure are not limited thereto. The second adhesive 3ad may include a thermally expandable microcapsule MC. For example, the second adhesive 3ad may be thermally expanded by the thermally expandable microcapsule MC. The second adhesive 3ad may be expanded in a manufacturing process so that an occupied area within an area in which the first adhesive 1ad is not arranged on the rear surface 5bs of the adhesive layer AL may be increased. A more detailed description thereof will be provided herein with reference to FIGS. 8 and 9. The content (e.g., amount) of the thermally expandable microcapsule MC of the second adhesive 3ad may be in a range of about 5 wt % to about 15 wt % based on 100 wt % of the second adhesive 3ad, but embodiments of the present disclosure are not limited thereto. A more detailed description of the thermally expandable microcapsule MC will be provided herein.

In one or more embodiments, the second adhesive 3ad may further include an optically expandable microcapsule. The optically expandable microcapsule may be defined as a microcapsule that reacts if (e.g., when) a light is radiated. The optically expandable microcapsule may include a photolysis material that reacts in a specific (e.g., set or predetermined) wavelength band inside the microcapsule, thereby obtaining substantially the same effect without heating. Further, because the optically expandable microcapsule is expanded only in a portion irradiated with a light, voids (or a degree or occurrence of voids) may be efficiently or suitably minimized or reduced without internal damage.

The third adhesive 5ad may be applied to (or on) the rear surface 5bs of the adhesive layer AL. In more detail, the third adhesive 5ad may be around (e.g., surround) the second adhesive 3ad on the rear surface 5bs of the adhesive layer AL as illustrated in FIG. 2. A thickness of the third adhesive 5ad may be in a range of about 20 μm to about 30 μm, but embodiments of the present disclosure are not limited thereto. The third adhesive 5ad may include the thermally expandable microcapsule MC. For example, the third adhesive 5ad may be thermally expanded by the thermally expandable microcapsule MC. The third adhesive 5ad may be expanded in a manufacturing process so that an occupied area within an area in which the first adhesive 1ad and the second adhesive 3ad are not arranged on the rear surface 5bs of the adhesive layer AL may be increased. A more detailed description thereof will be provided herein with reference to FIGS. 8 and 9. The content (e.g., amount) of the thermally expandable microcapsule MC of the third adhesive 5ad may be in a range of about 25 wt % to about 35 wt % based on 100 wt % of the third adhesive 5ad, but embodiments of the present disclosure are not limited thereto. For example, a thermal expansion rate of the third adhesive 5ad may be higher than a thermal expansion rate of the second adhesive 3ad.

The thermally expandable microcapsule MC may include a thermally expandable physical foaming agent. A thickness of the thermally expandable microcapsule MC may be in a range of about 2 μm and about 10 μm. The thermally expandable microcapsule MC may include a core part and a shell part. The core part may include a foaming agent to foam. For example, the core part may include a hydrocarbon material, but embodiments of the present disclosure are not limited thereto. If (e.g., when) heat is applied to the core part, the hydrocarbon may start gasification, an internal pressure may increase, and thus the core part may be expanded. The shell part may be around (e.g., surround) the core part. The shell part may include a polymer material. For example, the shell part may include a thermoplastic resin, but embodiments of the present disclosure are not limited thereto. If (e.g., when) heat is applied to the shell part, the shell part may be softened and expanded. For example, the thermally expandable microcapsule MC may be expanded by vaporizing the hydrocarbon in the core part while the shell is first softened by heating. As the thermally expandable microcapsule MC is used, the second adhesive 3ad and the third adhesive 5ad may be thermally expanded.

The fourth adhesive 7ad may be applied to (or on) rear surfaces of the second adhesive 3ad and the third adhesive 5ad. A rear surface of the fourth adhesive 7ad may be in contact with (e.g., may contact) the first plate UP of the vapor chamber VC. The fourth adhesive 7ad may include substantially the same material as the first adhesive 1ad. For example, the fourth adhesive 7ad may include a pressure sensitive adhesive.

The fourth adhesive 7ad may have an integral shape with the first adhesive 1ad. The first adhesive 1ad and the fourth adhesive 7ad may be different areas of the adhesive layer AL. The fourth adhesive 7ad may be an area that overlaps the second adhesive 3ad and the third adhesive 5ad of the adhesive layer AL. A thickness of the fourth adhesive 7ad may be smaller than a thickness of the first adhesive 1ad.

Referring to FIG. 2, as described in FIG. 1, the display panel DP, the vapor chamber VC, and the adhesive assembly AA may be heated to about 85° C. to about 95° C. in a stacked state, so that the thermally expandable microcapsule MC may be expanded. For example, the second adhesive 3ad and the third adhesive 5ad may be expanded and increase in volume by heating. The thermal expansion rate of the second adhesive 3ad may be smaller than the thermal expansion rate of the third adhesive 5ad. Thus, a volume if (e.g., when) the third adhesive 5ad is expanded may be greater than a volume if (e.g., when) the second adhesive 3ad is expanded.

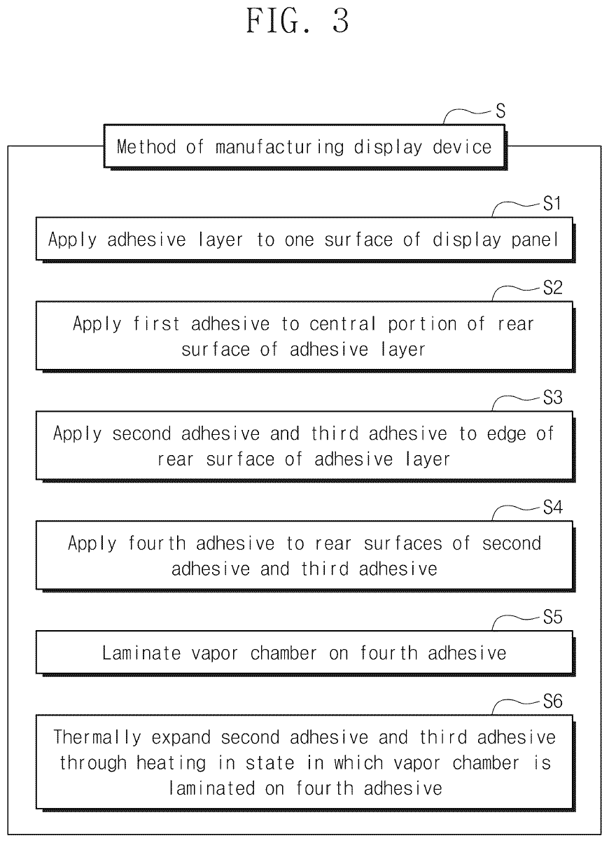

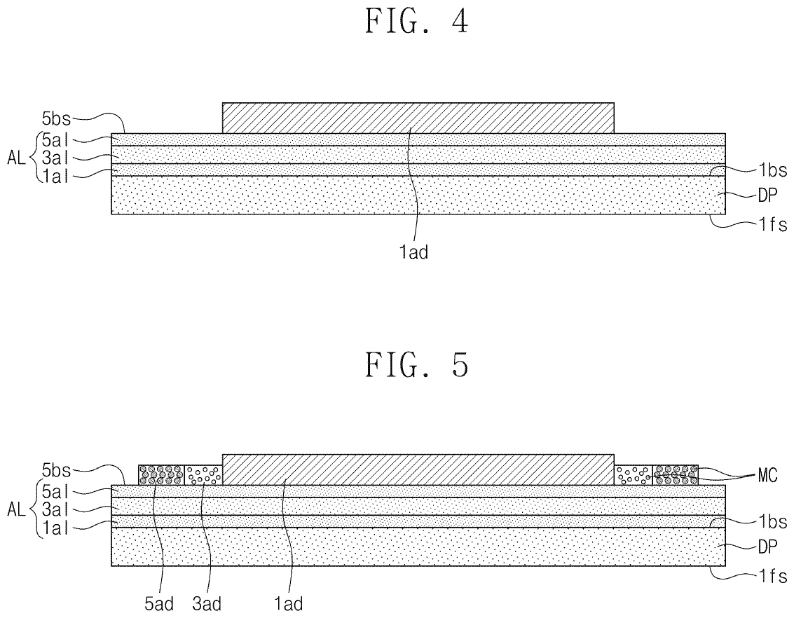

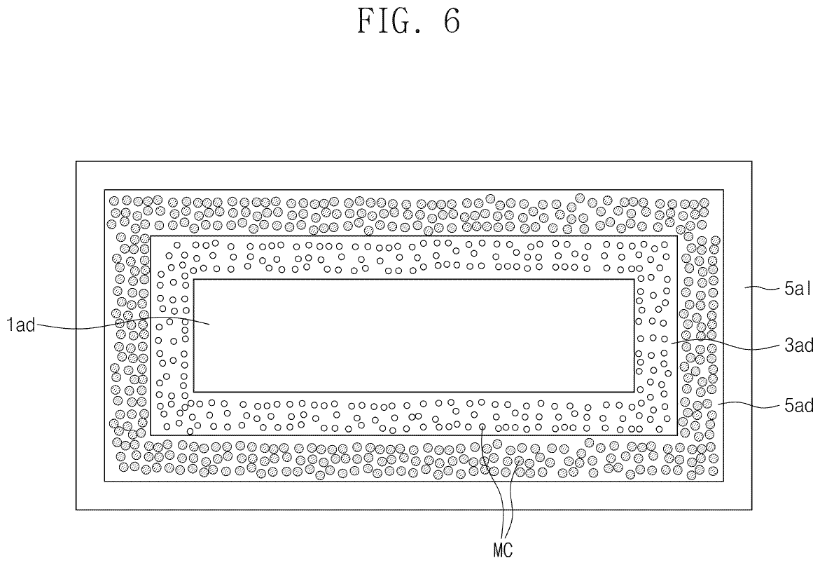

FIG. 3 is a flowchart illustrating a method of manufacturing a display device according to one or more embodiments of the present disclosure, and FIGS. 4 to 9 are views sequentially illustrating the method of manufacturing a display device according to the flowchart of FIG. 3.

Referring to FIG. 3, the method S of manufacturing a display device may include applying the adhesive layer AL to (or on) the rear surface 1bs of the display panel DP (S1), applying the first adhesive 1ad to (or on) the central portion of the rear surface 5bs of the adhesive layer AL (S2), applying the second adhesive 3ad and the third adhesive 5ad to an edge of the adhesive layer AL (S3), applying the fourth adhesive 7ad to (or on) the rear surfaces of the first adhesive 1ad, the second adhesive 3ad, and the third adhesive 5ad (S4), laminating the vapor chamber VC on the fourth adhesive 7ad (S5), and thermally expanding the second adhesive 3ad and the third adhesive 5ad through heating in a state in which the vapor chamber VC is laminated on the fourth adhesive 7ad (S6).

As illustrated in FIGS. 3 and 4, the applying of the adhesive layer AL to (or on) the rear surface 1bs of the display panel DP (S1) may include applying at least one adhesive layer AL and applying a plurality of adhesive layers AL. In more detail, the applying of the adhesive layer AL to (or on) the rear surface 1bs of the display panel DP (S1) may include applying the first adhesive layer 1al to (or on) the rear surface 1bs of the display panel DP, applying the second adhesive layer 3al onto the first adhesive layer 1al, and applying the third adhesive layer 5al onto the second adhesive layer 3al. The applying of the first adhesive layer 1al and the third adhesive layer 5al may be performed by applying substantially the same material. For example, each of the first adhesive layer 1al and the third adhesive layer 5al may include a PSA. The applying of the second adhesive layer 3al may be performed by applying a material different from that of the first adhesive layer 1al and/or the third adhesive layer 5al. For example, the second adhesive layer 3al may include polyethylene terephthalate (PET).

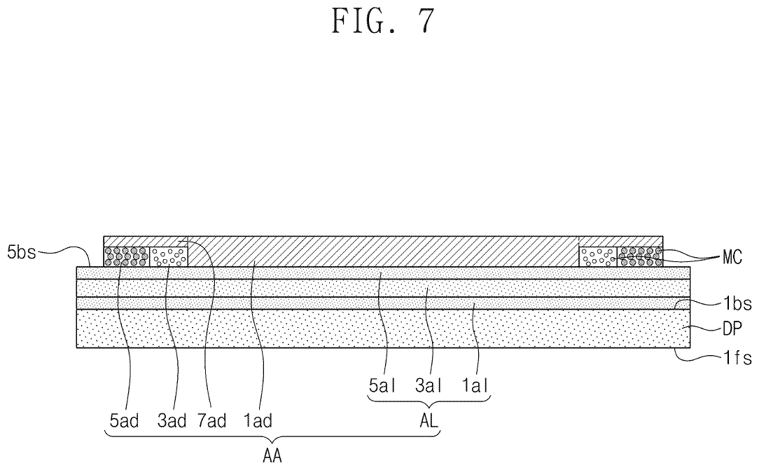

As illustrated in FIGS. 3 and 4, the applying of the first adhesive 1ad to (or on) the central portion of the rear surface 5bs of the adhesive layer AL (S2) may include directly applying the first adhesive 1ad to (or on) the rear surface of the third adhesive layer 5al. Further, the first adhesive 1ad may be flatly applied to fit the first plate UP of the vapor chamber VC (see FIG. 7).

As illustrated in FIGS. 3 to 6, the applying of the second adhesive 3ad and the third adhesive 5ad to the edge of the rear surface 5bs of the adhesive layer AL (S3) may include directly and respectively applying the second adhesive 3ad and the third adhesive 5ad to (or on) the rear surface of the third adhesive layer 5al. Further, the applying of the second adhesive 3ad and the third adhesive 5ad (S3) may include applying the second adhesive 3ad and the third adhesive 5ad, respectively, along the outside on the rear surface of the adhesive layer AL. The thicknesses of the second adhesive 3ad and the third adhesive 5ad (e.g., the thicknesses of each of the second adhesive 3ad and the third adhesive 5ad) may be smaller than the thickness of the first adhesive 1ad. On a plane (e.g., in a plan view), the applying of the second adhesive 3ad and the third adhesive 5ad along the outside of the adhesive layer AL may include applying the third adhesive 5ad to be around (e.g., surround) the second adhesive 3ad. For example, the third adhesive 5ad may be applied to the outside of the second adhesive 3ad. Further, the applying of the second adhesive 3ad and the third adhesive 5ad to the edge of the rear surface 5bs of the adhesive layer AL (S3) may include applying different materials to the second adhesive 3ad, the third adhesive 5ad, and the adhesive layer AL. In more detail, the applying of the second adhesive 3ad and the third adhesive 5ad to the edge of the rear surface 5bs of the adhesive layer AL (S3) may include applying a pressure sensitive adhesive containing the thermally expandable microcapsule MC. In the context of the present disclosure and unless otherwise defined, a plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if looking directly down onto the surface from above. In this context, the z-axis direction is perpendicular or normal to the horizontal plane defined by x-axis and y-axis directions.

As illustrated in FIGS. 3 and 7, the applying of the fourth adhesive 7ad to (or on) the rear surfaces of the first adhesive 1ad, the second adhesive 3ad, and the third adhesive 5ad (S4) may include applying the fourth adhesive 7ad to (or on) at least the rear surface of the first adhesive 1ad. For example, the fourth adhesive 7ad may be applied to (or on) the rear surfaces of the second adhesive 3ad and the third adhesive 5ad. The fourth adhesive 7ad may be applied such that the thickness of the fourth adhesive 7ad is smaller than the thickness of the first adhesive 1ad.

As illustrated in FIGS. 3 and 8, the laminating of the vapor chamber VC on the fourth adhesive 7ad (S5) may include arranging the first plate UP of the vapor chamber VC on the rear surface of the fourth adhesive 7ad. The vapor chamber VC may be attached (or fixed) by the fourth adhesive 7ad.

As illustrated in FIGS. 3 and 9, the thermally expanding of the second adhesive and the third adhesive through heating in a state in which the vapor chamber is laminated on the fourth adhesive (S6) may include heating at about 85° C. to about 95° C. In more detail, if (e.g., when) the display device DA in which the vapor chamber VC is attached to the adhesive assembly AA is heated to about 85° C. to about 95° C., volumes of the second adhesive 3ad and the third adhesive 5ad may increase. For example, the microcapsule MC contained in the thermally expandable second adhesive 3ad and the thermally expandable third adhesive 5ad may be thermally expanded. Accordingly, a void between the display panel DP and the vapor chamber VC may be minimized or reduced. Accordingly, the vapor chamber VC and the third adhesive layer 5al may be completely laminated, so that a temperature of an outer portion of the display panel DP may decrease. In more detail, a temperature of the outer portion of the display panel DP before the second adhesive 3ad and the third adhesive 5ad are expanded may be about 51.1° C. If (e.g., when) the second adhesive 3ad and the third adhesive 5ad are thermally expanded, the temperature of the display panel DP may be about 48.8° C. Thus, during temperature evaluation, a temperature difference that occurs between the display panel DP and the vapor chamber VC may decrease.

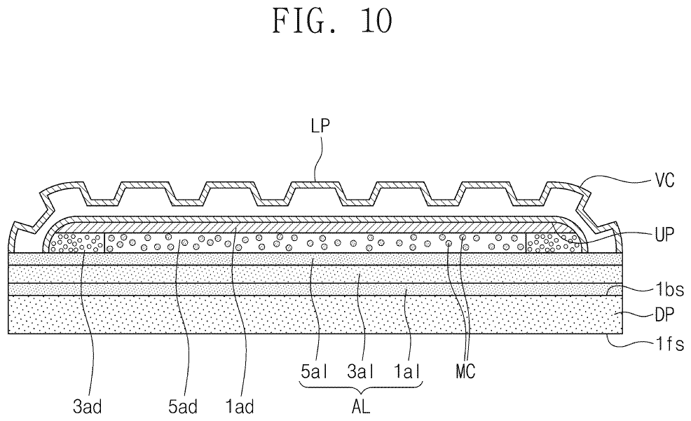

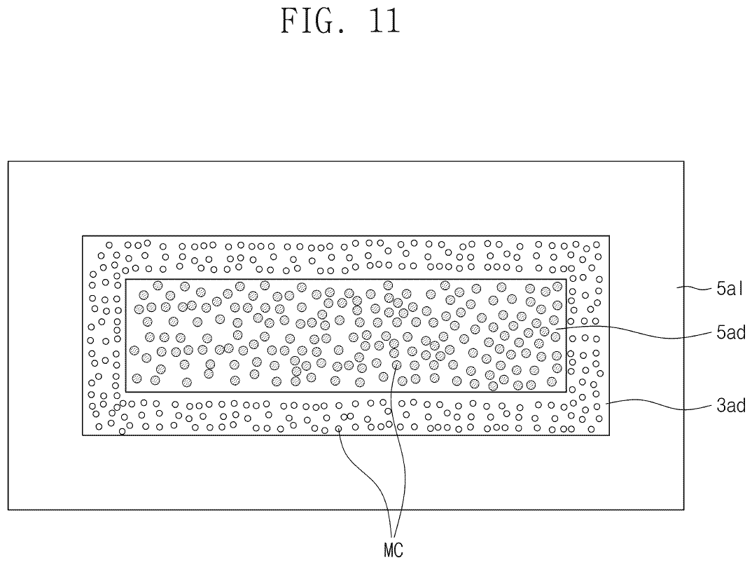

FIG. 10 is a cross-sectional view illustrating a display device according to one or more embodiments of the present disclosure, and FIG. 11 is a plan view illustrating a portion of the display device according to one or more embodiments of the present disclosure.

Hereinafter, descriptions substantially the same as or similar to those as described with reference to FIGS. 1 and 2 may not be provided.

Referring to FIGS. 10 and 11, a center of the vapor chamber VC may have a convex shape (e.g., a substantially convex shape) upward from the adhesive layer AL. For example, the first plate UP of the vapor chamber VC may have a dome shape (e.g., a substantially dome shape). In one or more embodiments, if (e.g., when) an upper side and a lower side are reversely illustrated, the vapor chamber VC may have a shape having a low central portion and a high outer portion. FIG. 10 illustrates a shape after the second adhesive 3ad and the third adhesive 5ad are expanded, but if (e.g., when) the second adhesive 3ad and the third adhesive 5ad are not expanded, an empty space may be provided between the third adhesive 5ad and the adhesive layer AL. The empty space provided between the third adhesive 5ad and the adhesive layer AL may be provided to minimize or reduce a stress applied to the central portion of the display panel DP if (e.g., when) the second adhesive 3ad and the third adhesive 5ad expand. The first adhesive 1ad, the second adhesive 3ad, and the third adhesive 5ad may be applied to the empty space between the vapor chamber VC and the adhesive layer AL. The fourth adhesive 7ad as illustrated in FIG. 1 may not be provided.

The first adhesive 1ad may be applied to (or on) the first plate UP of the vapor chamber VC. Further, the first adhesive 1ad may be applied onto the second adhesive 3ad and the third adhesive 5ad. The first adhesive 1ad may laminate the vapor chamber VC between the second adhesive 3ad and the third adhesive 5ad.

The second adhesive 3ad may be applied to (or on) the rear surface of the adhesive layer AL. In more detail, as illustrated in FIG. 4, the second adhesive 3ad may be arranged outside the third adhesive 5ad on the rear surface of the adhesive layer AL. The second adhesive 3ad may be arranged to be around (e.g., surround) the third adhesive 5ad. The second adhesive 3ad may fill a part between the vapor chamber VC and the adhesive layer AL during thermal expansion.

The third adhesive 5ad may be applied to be spaced and/or apart (e.g., spaced apart or separated) from the rear surface of the adhesive layer AL. In more detail, the third adhesive 5ad may not be in contact with (e.g., may not contact) the rear surface of the adhesive layer AL. A height if (e.g., when) the third adhesive 5ad is applied may be smaller than a height if (e.g., when) the second adhesive 3ad is applied. The third adhesive 5ad may be expanded by the thermally expandable microcapsule MC to fill an empty space between the vapor chamber VC and the adhesive layer AL.

According to a display device and a method of manufacturing a display device according to one or more embodiments of the present disclosure, a thermally expandable microcapsule may be thermally expanded, thereby minimizing or reducing voids (e.g., a degree or occurrence of voids).

According to a display device and a method of manufacturing a display device as described in one or more embodiments of the present disclosure, a temperature difference in the display device may be reduced. For example, the use of thermally expandable microcapsules in the adhesive layers of a display device may enhance its performance and reliability by filling voids and ensuring uniform (e.g., substantially uniform) bonding between the display panel and the vapor chamber. If (e.g., when) heated to about 85° C. to 95° C., these microcapsules expand, creating a continuous bond (e.g., a substantially continuous bond) that minimizes or reduces voids, improves or enhances heat dissipation, and stabilizes the operating temperature. This process may improve or enhance the structural integrity and thermal management of the device, allowing for precise control over adhesive properties and ensuring the device meets one or more suitable application requirements. Overall, embodiments of the present disclosure may result in a reliable, high-performing display device.

A display device, an electronic device, an electronic apparatus, a device for manufacturing substantially the same, and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

Although the subject matter of the present disclosure has been described with reference to the figures, those skilled in the art may understand that one or more embodiments of the present disclosure may be suitably modified and changed without departing from the spirit and scope of the present disclosure as defined by the appended claims and equivalents thereof. Moreover, it shall be appreciated that the disclosed embodiments are not intended to restrict the aspects and features of the present disclosure thereto and that the technical ideas and aspects of the present disclosure are interpreted to be included within the scope of the appended claims and their equivalents

What is claimed is:

1. A display device comprising:
a display panel;
a vapor chamber spaced from a rear surface of the display panel; and
an adhesive assembly between the rear surface of the display panel and the vapor chamber and arranged to attach the vapor chamber to the rear surface of the display panel,
wherein the adhesive assembly comprises:
an adhesive layer on the rear surface of the display panel;
a first adhesive at a central portion of a rear surface of the adhesive layer;
a second adhesive around the first adhesive on the rear surface of the adhesive layer;
a third adhesive around the second adhesive on the rear surface of the adhesive layer; and
a fourth adhesive on rear surfaces of the second adhesive and the third adhesive, and
wherein the second adhesive and the third adhesive comprise a thermally expandable microcapsule.

2. The display device as claimed in claim 1, wherein a thermal expansion rate of the third adhesive is higher than a thermal expansion rate of the second adhesive.

3. The display device as claimed in claim 1, wherein each of the adhesive layer, the first adhesive, the second adhesive, and the third adhesive comprises a pressure sensitive adhesive (PSA).

4. The display device as claimed in claim 1, wherein a thickness of each of the second adhesive and the third adhesive is in a range of about 20 μm to about 30 μm.

5. The display device as claimed in claim 1, wherein the adhesive layer comprises:
a first adhesive layer on the rear surface of the display panel;
a second adhesive layer on the first adhesive layer; and
a third adhesive layer on the second adhesive layer, and
wherein the second adhesive layer comprises polyethylene terephthalate (PET).

6. The display device as claimed in claim 1, wherein the second adhesive further comprises an optically expandable microcapsule.

7. The display device as claimed in claim 1, wherein the vapor chamber comprises:
a first plate coupled to the adhesive assembly; and
a second plate coupled to the first plate, and
wherein the second plate has a plurality of embossed structures arranged at regular intervals.

8. The display device as claimed in claim 7, wherein the first plate has a dome shape.

9. The display device as claimed in claim 1, wherein a thickness of the thermally expandable microcapsule is in a range of about 2 μm to about 10 μm.

10. The display device as claimed in claim 1, wherein a content of the thermally expandable microcapsule of the second adhesive is in a range of about 5 wt % to about 15 wt % based on 100 wt % of the second adhesive.

11. The display device as claimed in claim 1, wherein a content of the thermally expandable microcapsule of the third adhesive is in a range of about 25 wt % to about 35 wt % based on 100 wt % of the third adhesive.

12. The display device as claimed in claim 1, wherein the thermally expandable microcapsule comprises:
a core part comprising a hydrocarbon material; and
a shell part around the core part, and
wherein the shell part comprises a thermoplastic resin.

13. A method comprising:
applying an adhesive layer to a rear surface of a display panel;
applying a first adhesive to a central portion of a rear surface of the adhesive layer;
applying a second adhesive and a third adhesive to an edge of the rear surface of the adhesive layer;
applying a fourth adhesive to rear surfaces of the first adhesive, the second adhesive, and the third adhesive;
laminating a vapor chamber on the fourth adhesive; and
thermally expanding the second adhesive and the third adhesive through heating in a state in which the vapor chamber is laminated on the fourth adhesive,
wherein the applying of the second adhesive and the third adhesive to the edge of the rear surface of the adhesive layer comprises applying a pressure sensitive adhesive (PSA) comprising a thermally expandable microcapsule, and
wherein the method is a method of manufacturing a display device.

14. The method as claimed in claim 13, wherein the applying of the second adhesive and the third adhesive to the edge of the rear surface of the adhesive layer comprises applying the second adhesive and the third adhesive along an outside of the adhesive layer.

15. The method as claimed in claim 14, wherein the applying of the second adhesive and the third adhesive along the outside of the adhesive layer comprises applying the third adhesive around the second adhesive.

16. The method as claimed in claim 13, wherein a thickness of the fourth adhesive is smaller than a thickness of the first adhesive.

17. The method as claimed in claim 13, wherein the thermally expanding of the second adhesive and the third adhesive through heating in the state in which the vapor chamber is laminated on the fourth adhesive comprises heating at about 85° C. to about 95° C.

18. The method as claimed in claim 13, wherein the laminating of the vapor chamber on the fourth adhesive comprises laminating a first plate of the vapor chamber on a rear surface of the fourth adhesive.

19. The method as claimed in claim 13, wherein the applying of the adhesive layer to the rear surface of the display panel comprises:
applying a first adhesive layer to the rear surface of the display panel;
applying a second adhesive layer onto the first adhesive layer; and
applying a third adhesive layer onto the second adhesive layer,
wherein each of the first adhesive layer and the third adhesive layer comprises a pressure sensitive adhesive (PSA), and
wherein the second adhesive layer comprises polyethylene terephthalate (PET).

20. An electronic device comprising:
a display panel;
a vapor chamber spaced from a rear surface of the display panel; and
an adhesive assembly between the rear surface of the display panel and the vapor chamber and arranged to attach the vapor chamber to the rear surface of the display panel,
wherein the adhesive assembly comprises:
an adhesive layer on the rear surface of the display panel;
a first adhesive at a central portion of a rear surface of the adhesive layer;
a second adhesive around the first adhesive on the rear surface of the adhesive layer;
a third adhesive around the second adhesive on the rear surface of the adhesive layer; and
a fourth adhesive on rear surfaces of the second adhesive and the third adhesive, and
wherein the second adhesive and the third adhesive comprise a thermally expandable microcapsule.
